(19) United States
(12) Patent Application Publication
(10) Pub. No.: US 2020/0343200 A1
(43) Pub. Date: Oct. 29, 2020

(54) DIE EDGE CRACK MONITORING SYSTEMS

(71) Applicant: SK hynix Inc., Icheon-si Gyeonggi-do (KR)

(72) Inventor: Min Woo KIM, Seoul (KR)

(73) Assignee: SK hynix Inc., Icheon-si Gyeonggi-do (KR)

(21) Appl. No.: 16/677,180

(22) Filed: Nov. 7, 2019

(30) Foreign Application Priority Data
Apr. 24, 2019 (KR) 10-2019-0048090

(51) Int. Cl. H01L 23/58

(52) U.S. Cl. CPC H01L 23/585

(57) ABSTRACT

A crack monitoring system includes a crack sensor disposed in an edge region of a semiconductor die to detect an electrical short in the crack sensor.

### CROSS-REFERENCE TO RELATED APPLICATIONS

The present application claims priority under 35 U.S.C 119(a) to Korean Application No. 10-2019-0048090, filed on Apr. 24, 2019, which is incorporated herein by references in its entirety.

### BACKGROUND

### 1. Technical Field

The present disclosure relates to semiconductor technologies and, more particularly, to systems of monitoring edge cracks of semiconductor dies.

### 2. Related Art

Each of semiconductor dies may include integrated circuits in which a plurality of patterns are integrated. The plurality of patterns may be realized on a semiconductor wafer. The semiconductor wafer including the integrated circuits may be cut into a plurality of pieces to provide the semiconductor dies. At least one of the semiconductor dies may be encapsulated to form a semiconductor package.

While the semiconductor wafer is cut using a die sawing process or the semiconductor dies are encapsulated using a packaging technique, cracks may be undesirably generated in the semiconductor dies. In particular, the cracks may be generated in edge regions of the semiconductor dies during the die sawing process for cutting the semiconductor wafer.

The cracks formed in the edge regions of the semiconductor dies may cause failures of the semiconductor dies or the semiconductor packages. Various techniques have been proposed to detect the edge cracks of the semiconductor dies. Nevertheless, it may be difficult to detect the edge cracks having a fine size. Accordingly, a lot of effort has been focused on developing methods of detecting the fine edge cracks more accurately.

### SUMMARY

According to an embodiment, a crack monitoring system includes a semiconductor die including a central region and an edge region surrounding the central region, a crack sensor disposed in the edge region of the semiconductor die. The crack sensor includes a first conductive line and a second conductive line disposed to be spaced apart from each other, a conductive diffusible material pattern disposed to be spaced apart from the first and second conductive lines, and a diffusion barrier layer encapsulating the conductive diffusible material pattern.

### BRIEF DESCRIPTION OF THE DRAWINGS

FIG. 1 illustrates a crack monitoring system according to an embodiment.

FIG. 2 is a cross-sectional view taken along a line X-X′ of FIG. 1.

FIG. 3 is a cross-sectional view illustrating a crack generated in an edge region of an example of a semiconductor die.

FIG. 4 is a cross-sectional view illustrating a short circuit due to the crack shown in FIG. 3.

### DETAILED DESCRIPTION

The terms used herein may correspond to words selected in consideration of their functions in the embodiments, and the meanings of the terms may be construed to be different according to ordinary skill in the art to which the embodiments belong. If defined in detail, the terms may be construed according to the definitions. Unless otherwise defined, the terms (including technical and scientific terms) used herein have the same meaning as commonly understood by one of ordinary skill in the art to which the embodiments belong.

It will be understood that although the terms “first,” “second,” “third” etc. may be used herein to describe various elements, these elements should not be limited by these terms. These terms are only used to distinguish one element from another element, but not used to define only the element itself or to mean a particular sequence.

It will also be understood that when an element or layer is referred to as being “on,” “over,” “below,” “under,” or “outside” another element or layer, the element or layer may be in direct contact with the other element or layer, or intervening elements or layers may be present. Other words used to describe the relationship between elements or layers should be interpreted in a like fashion (e.g., “between” versus “directly between” or “adjacent” versus “directly adjacent”).

Spatially relative terms, such as “beneath,” “below,” “lower,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented above the other elements or features. The device may be otherwise oriented (rotated 90 degrees or at other orientations) and the spatially relative descriptors used herein interpreted accordingly.

A semiconductor package may include electronic devices such as semiconductor chips or semiconductor dies. The semiconductor chips or the semiconductor dies may be obtained by separating a semiconductor substrate such as a wafer into a plurality of pieces using a die sawing process. The semiconductor chips may correspond to memory chips, logic chips, or application specific integrated circuits (ASIC) chips. The memory chips may include dynamic random access memory (DRAM) circuits, static random access memory (SRAM) circuits, NAND-type flash memory circuits, NOR-type flash memory circuits, magnetic random access memory (MRAM) circuits, resistive random access memory (ReRAM) circuits, ferroelectric random access memory (FeRAM) circuits or phase change random access memory (PcRAM) circuits which are integrated on the semiconductor substrate. The semiconductor package may be employed in communication systems such as mobile phones, electronic systems associated with biotechnology or health care, or wearable electronic systems. The semiconductor packages may be applicable to internet of things (IoT).

Same reference numerals refer to same elements throughout the specification. Even though a reference numeral is not mentioned or described with reference to a drawing, the reference numeral may be mentioned or described with reference to another drawing. In addition, even though a reference numeral is not shown in a drawing, it may be mentioned or described with reference to another drawing.

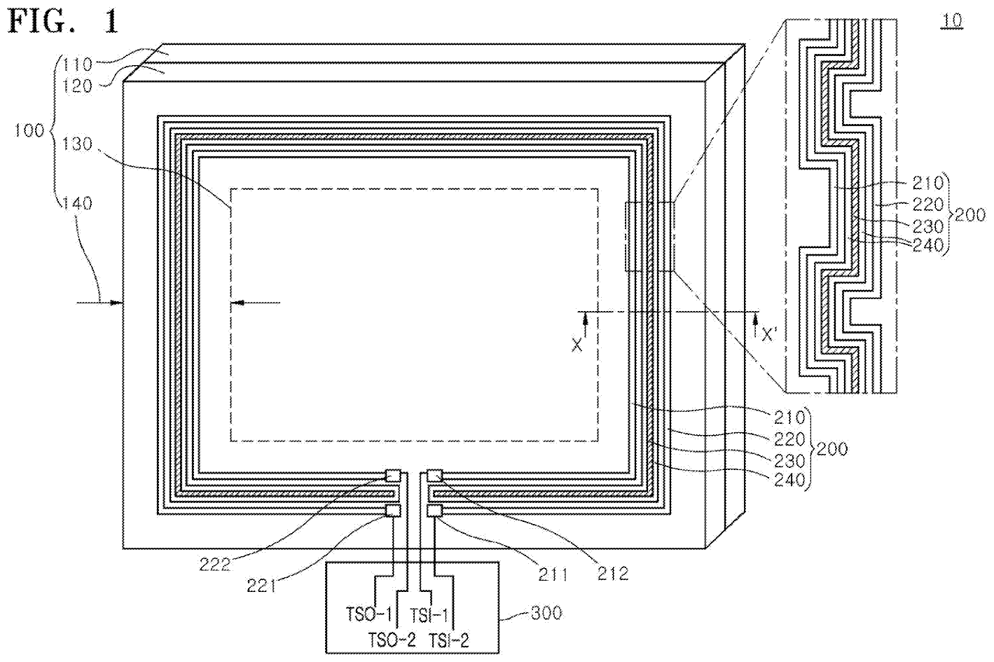

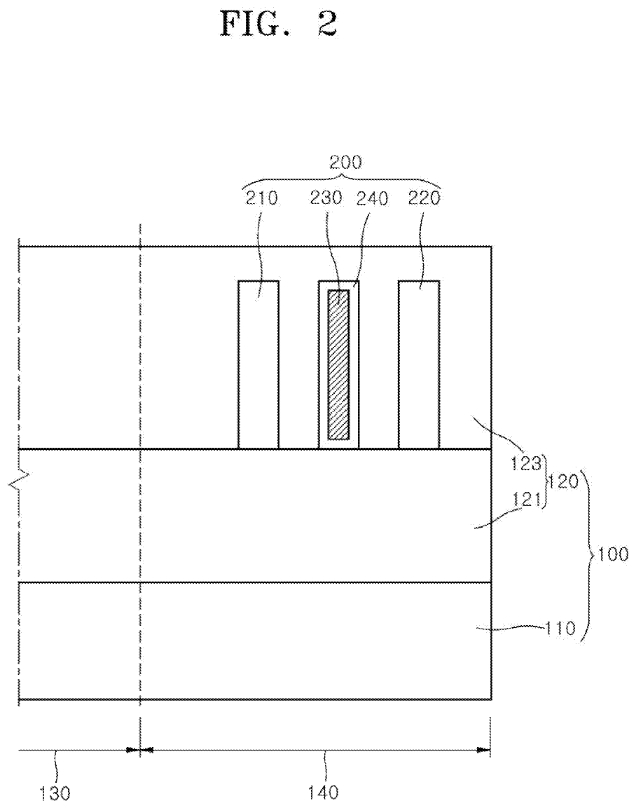

FIG. 1 illustrates a crack monitoring system 10 according to an embodiment. FIG. 2 is a cross-sectional view taken along a line X-X′ of FIG. 1.

Referring to FIGS. 1 and 2, the crack monitoring system 10 may be configured to include a semiconductor die 100, a crack sensor 200 and a crack monitor 300. The crack monitoring system 10 may be configured to detect fine cracks generated in an edge region 140 of the semiconductor die 100. The crack monitoring system 10 may be configured to detect the fine cracks by monitoring electrical signals, which are sensed by the crack sensor 200, with the crack monitor 300.

The semiconductor die 100 may include a central region 130 and the edge region 140. The semiconductor die 100 may be configured to include a semiconductor substrate 110 and an inter-layer dielectric layer 120 disposed on the semiconductor substrate 110. The semiconductor substrate 110 may include a semiconductor material such as a silicon material. Integrated circuits (not shown) may be formed in or on the central region 130 of the semiconductor substrate 110. A metal interconnection structure (not shown) connected to the integrated circuits may be disposed in the inter-layer dielectric layer 120 located in the central region 130. The inter-layer dielectric layer 120 may include a plurality of dielectric layers which are stacked. For example, the inter-layer dielectric layer 120 may include a first dielectric layer 121 disposed on a surface of the semiconductor substrate 110 and a second dielectric layer 123 disposed on a surface of the first dielectric layer 121 opposite to the semiconductor substrate 110, as illustrated in FIG. 2.

No integrated circuit is disposed in the edge region 140 of the semiconductor die 100. Fine cracks may be generated in the edge region 140 of the semiconductor die 100. When the semiconductor die 100 is separated from a semiconductor wafer by a die sawing process, the fine cracks may be formed in the edge region 140 of the semiconductor die 100 by a physical force generated during the die sawing process. Alternatively, the fine cracks may be formed in the edge region 140 of the semiconductor die 100 by a physical force generated during a packaging process of the semiconductor die 100.

The crack sensor 200 may be configured to detect the fine cracks. The crack sensor 200 may be disposed in the edge region 140 of the semiconductor die 100. The crack sensor 200 may be disposed in the inter-layer dielectric layer 120 located in the edge region 140 of the semiconductor die 100. The crack sensor 200 may be disposed to surround the central region 130 of the semiconductor die 100 in a plan view.

The crack sensor 200 may include a pair of conductive lines, for example, a first conductive line 210 and a second conductive line 220. A conductive diffusible material pattern 230 may be disposed to be adjacent to the first and second conductive lines 210 and 220. The first and second conductive lines 210 and 220 may be disposed to be spaced apart from each other. For example, as illustrated in FIG. 2, the first conductive line 210 may be disposed in the edge region 140 to be relatively closer to the central region 130 than the second conductive line 220 is close to the central region 130. That is, the second conductive line 220 may be disposed in the edge region 140 to be relatively further from the central region 130 than the first conductive line 210 is far from the central region 130. The conductive diffusible material pattern 230 may be disposed between the first and second conductive lines 210 and 220. The conductive diffusible material pattern 230 may be disposed to be spaced apart from both of the first and second conductive lines 210 and 220.

Referring to FIG. 2, the first conductive line 210, the second conductive line 220 and the conductive diffusible material pattern 230 may be disposed on the first dielectric layer 121, and the second dielectric layer 123 may be disposed to cover and electrically insulate the first conductive line 210, the second conductive line 220 and the conductive diffusible material pattern 230 from each other. Because the first conductive line 210, the second conductive line 220 and the conductive diffusible material pattern 230 are disposed side-by-side on the first dielectric layer 121, the first conductive line 210, the second conductive line 220 and the conductive diffusible material pattern 230 may be located at substantially the same level. In another embodiment, although not shown in the drawings, first and second conductive lines corresponding to the first and second conductive lines 210 and 220 may be disposed side-by-side to be spaced apart from each other at a first level, and a conductive diffusible material pattern corresponding to the conductive diffusible material pattern 230 may be located at a second level different from the first level. In yet another embodiment, although not shown in the drawings, a first conductive line corresponding to the first conductive line 210, a conductive diffusible material pattern corresponding to the conductive diffusible material pattern 230, and a second conductive line corresponding to the second conductive line 220 may be sequentially stacked in a vertical direction.

Referring again to FIG. 1, the first and second conductive lines 210 and 220 and the conductive diffusible material pattern 230 may extend to surround the central region 130 of the semiconductor die 100. The first and second conductive lines 210 and 220 may extend to have an open loop shape surrounding the central region 130 in a plan view. A first input terminal 212 and a first output terminal 222 may be connected to both ends of the first conductive line 210, respectively. A second input terminal 211 and a second output terminal 221 may be connected to both ends of the second conductive line 220, respectively. The conductive diffusible material pattern 230 may extend to be parallel with the first and second conductive lines 210 and 220 to have an open loop shape in a plan view.

In order to increase a range of a cover region in which the crack sensor 200 is able to detect cracks, it may be necessary to increase a length of the first and second conductive lines 210 and 220. For example, the first and second conductive lines 210 and 220 may be designed to have a zigzag shape, a saw tooth shape or a bent shape in a plan view. In such a case, the conductive diffusible material pattern 230 may also be designed to have a zigzag shape, a saw tooth shape or a bent shape in a plan view.

Referring again to FIG. 2, the first and second conductive lines 210 and 220 of the crack sensor 200 may be disposed to be electrically insulated and isolated from each other. The second dielectric layer 123 covering the first and second conductive lines 210 and 220 may electrically insulate and isolate the first and second conductive lines 210 and 220 from each other. The conductive diffusible material pattern 230 may be disposed to be electrically insulated and isolated from the first and second conductive lines 210 and 220. The conductive diffusible material pattern 230 may be electrically insulated and isolated from the first and second conductive lines 210 and 220 by the second dielectric layer 123.

A diffusion barrier layer 240 may be formed to encapsulate the conductive diffusible material pattern 230. The conductive diffusible material pattern 230 may be formed to include a diffusible material such as a copper material having a relatively high diffusivity. The first or second conductive line 210 or 220 may be formed to include an aluminum material, a tungsten material or a polysilicon material.

The diffusion barrier layer 240 may be formed to prevent the diffusible material in the conductive diffusible material pattern 230 from being diffused into the inter-layer dielectric layer 120 when the semiconductor die 100 has a normal state without any crack. The diffusion barrier layer 240 may be formed to include a dielectric material such as a silicon nitride (SiN) material. In order to enhance a diffusion barrier property of the diffusion barrier layer 240, the diffusion barrier layer 240 may be formed to include an iridium (Ir) layer, a platinum (Pt) layer, a titanium (Ti) layer, a ruthenium (Ru) layer, a cobalt (Co) layer or a nickel (Ni) layer. For example, the diffusion barrier layer 240 may be formed of a combination of a platinum (Pt) layer and a titanium (Ti) layer, a combination of a nickel (Ni) layer and a titanium (Ti) layer, or a combination of a cobalt (Co) layer and a tantalum (Ta) layer.

Referring again to FIG. 1, the crack monitor 300 may be disposed in an outside region of the semiconductor die 100. The crack monitor 300 may be electrically connected to the crack sensor 200. The crack monitor 300 may be configured to detect an electrical short in the crack sensor 200. The crack monitor 300 may detect whether an electrical short between the first and second conductive lines 210 and 220 exists or not. The crack monitor 300 may regard the edge region 140 as a defective region having a crack if an electrical short between the first and second conductive lines 210 and 220 is detected.

The crack monitor 300 may be configured to apply a first test input signal TSI-1 to the first conductive line 210 through the first input terminal 212 of the first conductive line 210 and to receive a first test output signal TSO-1 from the second output terminal 221 of the second conductive line 220. The first test input signal TSI-1 may be a first input current flowing through the first conductive line 210. The first test output signal TSO-1 may be a first output current outputted from the first conductive line 210.

In an embodiment, the crack monitor 300 may be configured to apply a second test input signal TSI-2 to the second conductive line 220 through the second input terminal 211 of the second conductive line 220 and to receive a second test output signal TSO-2 from the first output terminal 222 of the first conductive line 210. The second test input signal TSI-2 may be a second input current flowing through the second conductive line 220. The second test output signal TSO-2 may be a second output current outputted from the second conductive line 220.

When the semiconductor die 100 has a normal state without a crack or any cracks in the edge region 140, the first and second conductive lines 210 and 220 may be electrically insulated and isolated from each other. In the normal state, if the first test input signal TSI-1 is applied to the first conductive line 210, a current value of the first test output signal TSO-1 outputted from the second conductive line 220 may be a first current value. In an embodiment, the first current value may be substantially zero amperes. This is because no current substantially flows between the first and second conductive lines 210 and 220 which are electrically insulated and isolated from each other.

When a fine crack is formed in the edge region 140 of the semiconductor die 100, the first and second conductive lines 210 and 220 may be electrically connected to each other. In such a case, if the first test input signal TSI-1 is applied to the first conductive line 210, a current value of the first test output signal TSO-1 outputted from the second conductive line 220 may be different from the current value in the normal state. For example, if the first test input signal TSI-1 is applied to the first conductive line 210, a current value of the first test output signal TSO-1 outputted from the second conductive line 220 may be substantially non-zero amperes. This is because a current substantially flows between the first and second conductive lines 210 and 220 which are electrically connected to each other.

The crack monitor 300 may measure a current value of the first test output signal TSO-1 outputted from the second conductive line 220. If the current value of the first test output signal TSO-1 is non-zero, the edge region 140 may be regarded as a defective edge region having a crack generated between the first and second conductive lines 210 and 220. In an embodiment, if the current value of the first test output signal TSO-1 is different from a current value of the first test output signal TSO-1 in the normal state, without a crack or any cracks in the edge region 140, then the edge region 140 may be regarded as a defective edge region having a crack generated between the first and second conductive lines 210 and 220.

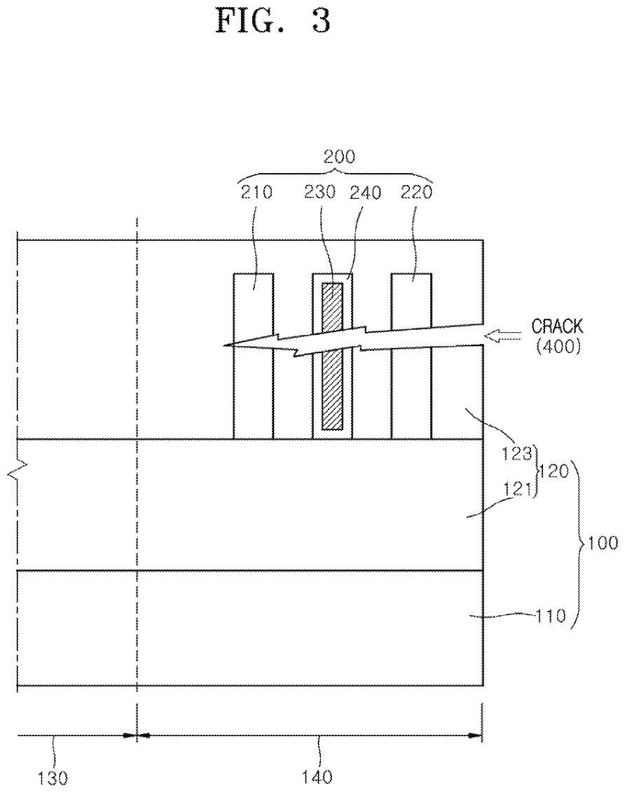

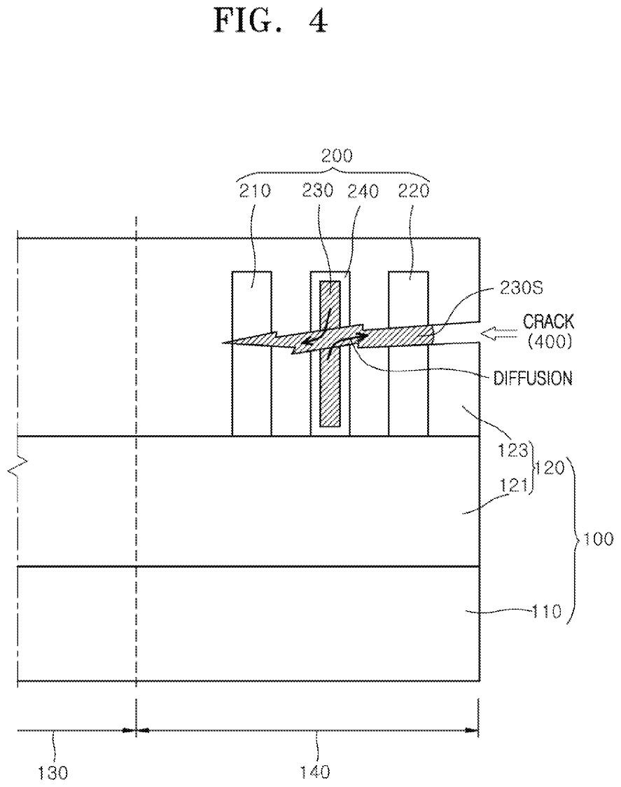

FIG. 3 is a cross-sectional view illustrating a crack 400 generated in the edge region 140 of the semiconductor die 100. FIG. 4 is a cross-sectional view illustrating a short circuit due to the crack 400 shown in FIG. 3.

Referring to FIG. 3, if the crack 400 is formed in the edge region 140 of the semiconductor die 100, the crack 400 may break the diffusion barrier layer 240 to spread out. If the diffusion barrier layer 240 is broken by the crack 400 or the crack 400 infiltrates into the diffusion barrier layer 240, the conductive diffusible material pattern 230 encapsulated by the diffusion barrier layer 240 may be revealed and exposed to the crack 400.

Referring to FIG. 4, a diffusible material included in the conductive diffusible material pattern 230 may be diffused along the crack 400 to form a diffusion layer 230S. The diffusion layer 230S may extend to electrically connect the first and second conductive lines 210 and 220 to each other. That is, the diffusion layer 230S may electrically connect the first and second conductive lines 210 and 220 to each other to function as a short circuit between the first and second conductive lines 210 and 220.

As described above, when the crack 400 is generated in the edge region 140, a diffusible material included in the conductive diffusible material pattern 230 may be diffused to form the diffusion layer 230S, and the diffusion layer 230S may function as a short circuit electrically connecting the first and second conductive lines 210 and 220 to each other. The crack monitor 300 illustrated in FIG. 1 may detect electrical short between the first and second conductive lines 210 and 220 of the crack sensor 200 and may regard the edge region 140 as a defective region having a crack if the first and second conductive lines 210 and 220 are electrically connected to each other by a short circuit therebetween. While the crack 400 in the edge region 140 is detected by the crack sensor 200 and the crack monitor 300, heat for accelerating diffusion of the diffusible material included in the conductive diffusible material pattern 230 may be applied to the semiconductor die 100 to more readily form the diffusion layer 230S.

Embodiments of the present disclosure have been disclosed for illustrative purposes. Those skilled in the art will appreciate that various modifications, additions and substitutions are possible, without departing from the scope and spirit of the present disclosure and the accompanying claims.

What is claimed is:

1. A crack monitoring system comprising:
a semiconductor die including a central region and an edge region surrounding the central region; and
a crack sensor disposed in the edge region of the semiconductor die,
wherein the crack sensor includes:
a first conductive line and a second conductive line disposed to be spaced apart from each other;
a conductive diffusible material pattern disposed to be spaced apart from the first and second conductive lines; and
a diffusion barrier layer encapsulating the conductive diffusible material pattern.

2. The crack monitoring system of claim 1, wherein the conductive diffusible material pattern is disposed between the first and second conductive lines.

3. The crack monitoring system of claim 1, wherein the first and second conductive lines and the conductive diffusible material pattern extend to substantially surround the central region of the semiconductor die.

4. The crack monitoring system of claim 1, wherein the first and second conductive lines are electrically isolated from each other.

5. The crack monitoring system of claim 1, wherein the conductive diffusible material pattern is electrically isolated from the first and second conductive lines.

6. The crack monitoring system of claim 1, wherein each of the first and second conductive lines includes an aluminum material.

7. The crack monitoring system of claim 1, wherein each of the first and second conductive lines includes a tungsten material.

8. The crack monitoring system of claim 1, wherein the conductive diffusible material pattern includes a copper material.

9. The crack monitoring system of claim 1, further comprising:
a crack monitor configured to detect an electrical short in the crack sensor.

10. The crack monitoring system of claim 9, wherein the crack monitor is configured to detect an electrical short between the first and second conductive lines, and the edge region is regarded as a defective region having a crack when the first and second conductive lines are electrically connected to each other by an electrical short therebetween.

11. The crack monitoring system of claim 10, wherein the edge region is regarded as the defective region having the crack when the first and second conductive lines are electrically connected to each other by a diffusible material originally included in the conductive diffusible material pattern which has diffused along the crack to form a diffusion layer which electrically connects the first and second conductive lines to each other.

12. The crack monitoring system of claim 1, further comprising:
a crack monitor configured to apply a first test input signal to the first conductive line through a first input terminal and provide a current value of a first test output signal outputted from the second conductive line through a second output terminal.

13. The crack monitoring system of claim 12,
wherein the semiconductor die has a normal state when the first and second conductive lines are electrically insulated and isolated from each other and the first test output signal has a first current value, and
wherein the edge region is regarded as the defective region having the crack when the current value of the first test output signal is different from the first current value of the first test output signal when the semiconductor die has the normal state.

14. The crack monitoring system of claim 13, wherein the first current value is substantially zero amperes.
